(19) United States
(12) Patent Application Publication
(10) Pub. No.: US 2009/0189179 A1
(43) Pub. Date: Jul. 30, 2009

(54) METHOD FOR MANUFACTURING LIGHT EMITTING DIODE PACKAGE

(76) Inventors: Fong-Yuan Wen, Taoyuan City (TW); Yu-Kang Chang, Taoyuan City (TW)

Correspondence Address: HDLS Patent & Trademark Services, P.O. BOX 220746, CHANTILLY, VA, 20153-0746, US

(21) Appl. No.: 12/020,939

(22) Filed: Jan. 28, 2008

(51) Int. Cl. H01L 33/00; H01L 21/00

(52) U.S. Cl. 257/100; 438/26; 257/E33.001; 257/E21.001

(57) ABSTRACT

A method for manufacturing flip-chip light emitting diode (LED) package. A recess array is formed at the top surface of a silicon wafer. Two through-wafer via holes are formed in the recess. A plurality of LED chips are flip-chip mounted in each of the recesses, respectively. Two electrodes of each LED chip are respectively covered the two via holes. An encapsulator for encapsulating each LED chip is arranged in the recess to provide a flat top surface. A metal layer is deposited on the bottom surface of the silicon wafer to electrically connecting with the electrodes through the two via holes. Metal lines which electrically connecting the electrodes are formed by patterning the metal layer. A plurality of silicon submounts, each including at least one recess, are cut off from the silicon wafer. A fluorescent layer is arranged on the top surface of the encapsulator.

### BACKGROUND OF THE INVENTION

1. Field of the Invention

The present invention relates to a method of manufacturing light emitting diode package, especially to a method of manufacturing light emitting diode package with uniform phosphor layer.

2. Description of Prior Art

Light emitting diode (LED) has the advantages such as fast response rate, long-term life time and compact volume so as to be widely used as a light source of indicator or display. Since the white LED is successfully developed with the illuminating efficiency increased, the applications of LED in the general lighting field gradually get more attention.

FIG. 1 shows a prior art high-power LED package disclosed by US patent publication No. 20050274959. A silicon submount 402 for carrying the LED chip 401 is introduced. The LED chip 401 is electrically bonding to the silicon submount 402 with the flip-chip approach. The silicon submount 402 is arranged on a heatsink 409 for heat dissipating purpose. The electrodes of silicon submount 402 are electrically connected to external electrodes 406a, 406b on the heatsink 409 by bonding wires 412a, 412b.

However, it is difficult to control the thickness uniformity of a phosphor layer arranged in the recess of the silicon submount with traditional dispensing approach. The poor thickness uniformity of the phosphor layer leads to poor illuminating uniformity of the light emitting diode package.

Moreover, the electrodes of the silicon submount 402 are limited to electrically connect to the external electrodes 406a, 406b by wire bonding process and the light emitting diode package is not compatible with the surface mount process which comprehensively adopted by current semiconductor industry.

### SUMMARY OF THE INVENTION

It is the object of the present invention to a method of manufacturing light emitting diode package with uniform phosphor layer and the light emitting diode package thereof is compatible with the surface mount process.

Accordingly, the present invention provides a method of manufacturing light emitting diode package.

A silicon wafer is provided. A recess array is formed at the top surface of the silicon wafer. Two through-wafer via holes are formed in each recess. A plurality of LED chips are respectively flip-chip mounted in each of the recesses. Two electrodes of each LED chip are respectively covered the two via holes. An encapsulator for encapsulating each LED chip is arranged in the recess. A flat top surface is provided by the encapsulator. A metal layer is deposited on the bottom surface of the silicon wafer to electrically connecting with the electrodes through the via holes. Metal lines which electrically connecting the electrodes are formed by patterning the metal layer. A plurality of silicon submounts which each includes at least one recess are cut off from the silicon wafer. A fluorescent layer is arranged on the top surface of the encapsulator.

### BRIEF DESCRIPTION OF DRAWING

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 shows a prior art high-power LED package.

FIG. 2 shows the flowchart of the method for manufacturing flip-chip light emitting diode package according to the preferred embodiment of the present invention.

FIGS. 3A to 3G are sectional views corresponding to steps in FIG. 2.

FIG. 4 shows one kind of electrodes arrangement of the LED.

FIG. 5 shows another kind of electrodes arrangement of the LED.

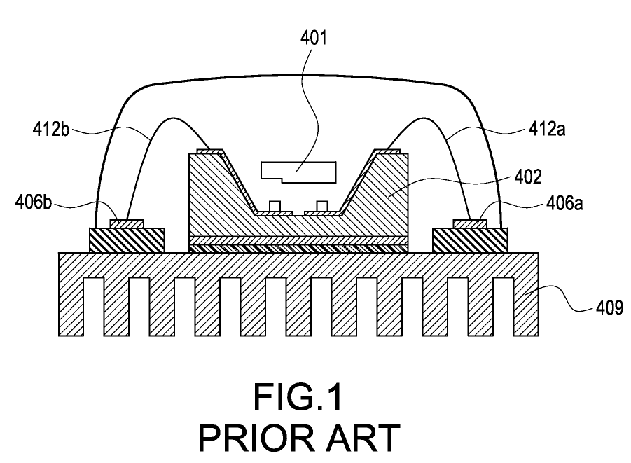

### DETAILED DESCRIPTION OF THE INVENTION

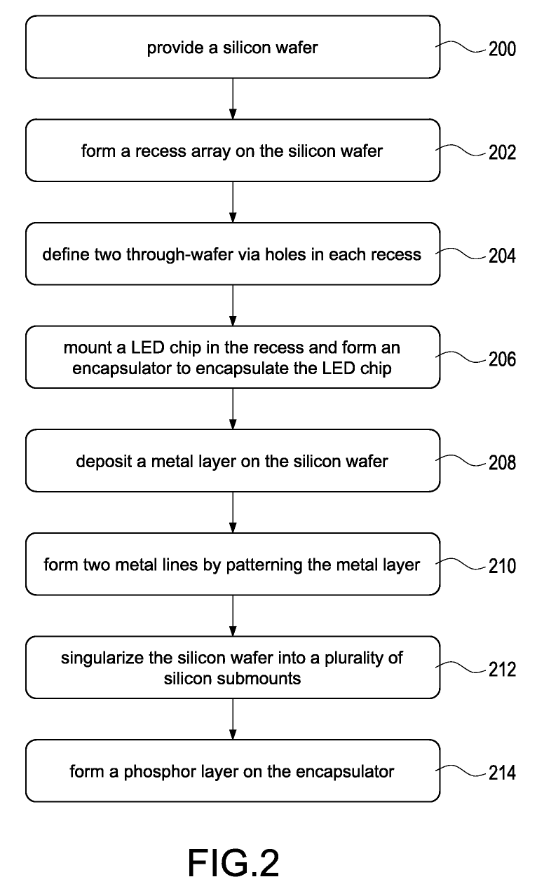

FIG. 2 shows the flowchart of the method for manufacturing flip-chip light emitting diode package according to the preferred embodiment of the present invention.

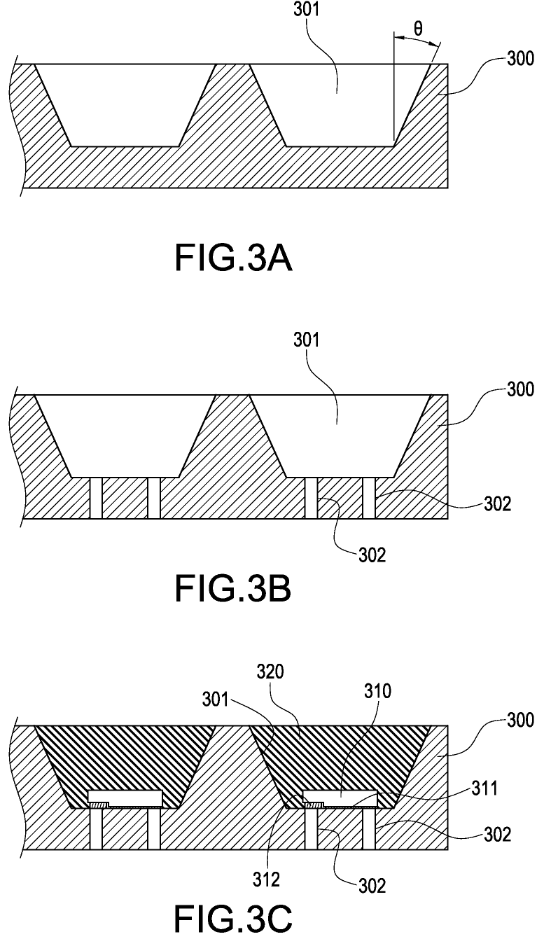

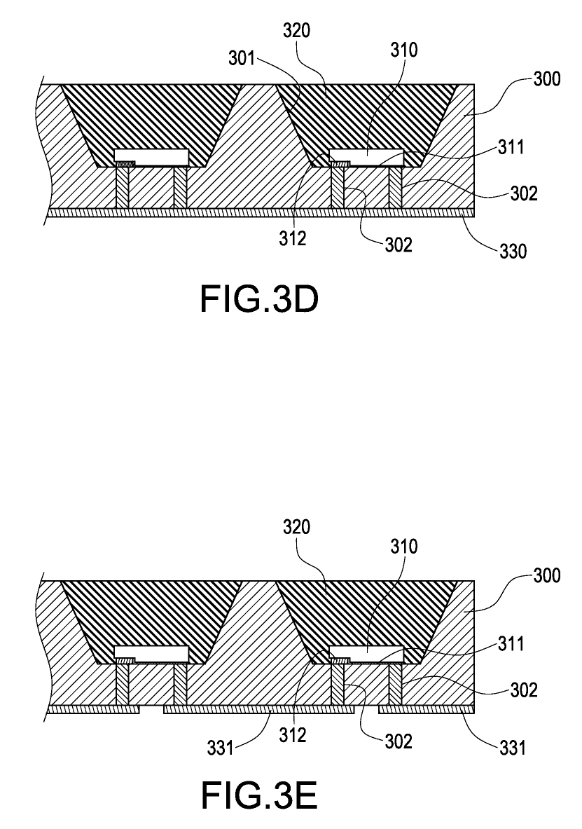

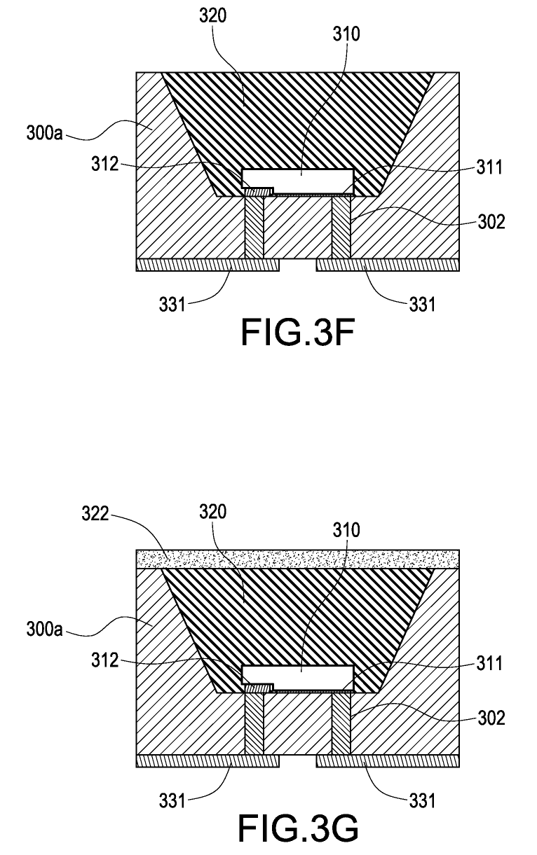

In step 200, first, an epitaxial silicon wafer 300 is provided. The silicon wafer 300 has a top surface and a bottom surface. In step 202, with reference also to FIG. 3A, an anisotropic wet etching is performed on the top surface of the silicon wafer 300 to form a recess array 300. The recess array 300 includes a plurality of recesses 301 arranged in a matrix form. The anisotropic wet etching can be performed by KOH or TMAH etchants. Each recess has a depth of 100-400 mm. The angle θ between the peripheral surface of the recess and the normal direction of the bottom surface of the recess is of 45-75 degree.

In step 204, with reference also to FIG. 3B, two through-wafer via holes 302 are defined on the base portion of each recess 301 by punching through or laser drilling.

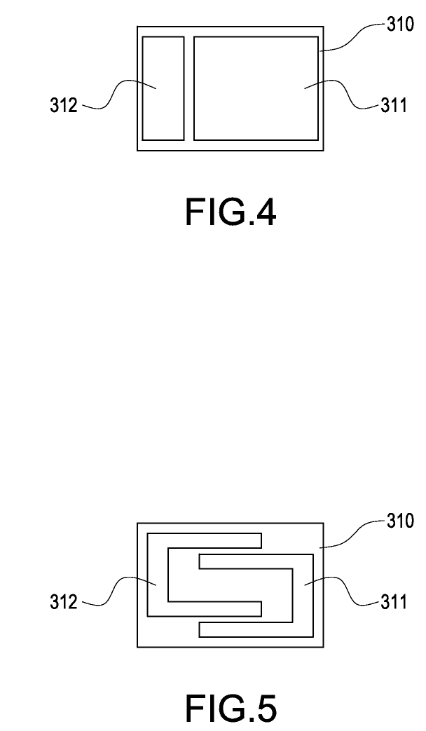

In step 206, with reference also to FIG. 3C, a plurality of LED chips 310 are provided. Each LED chip 310 is flip-chip mounted on the base portion of each recess 301. Two electrodes 311,312 of the LED chip 310 are arranged to cover the two via holes 302, respectively. The LED chip 310, for example, can be a GaN-based blue LED chip and the two electrodes 311,312 of the LED chip 310 are located on the same bottom surface of the LED chip 310. Then, an encapsulator 320 for encapsulating each LED chip 310 is arranged in each recess 301 with dispensing approach. A flat top surface is provided by the encapsulator 320. The flat top surface of the encapsulator 320 preferably coincides with the top surface of the silicon wafer 300. The encapsulator 320 can be single layer coating or multiple layer coatings of silicone. The refractive index of the encapsulator 320 can be adjusted by composition or process condition tuning, so as to achieve index matching with the refractive index of LED chip 310. FIGS. 4 and 5 show two kinds of arrangement of the electrodes on the LED chip 310. Moreover, the arrangement in FIG. 5 has enhanced illumination efficiency.

In step 208, with reference also to FIG. 3D, a metal layer 330 is deposited on the bottom surface of the silicon wafer 300. The metal layer 330 is electrically connected to the two electrodes of each LED chip 310 through the via holes 302. In the present embodiment, the metal layer 330 has a stacked structure consisting of a Chromium (Cr) layer deposited on the bottom surface of the silicon wafer 300, and a Copper (Cu) layer deposited on the bottom surface of the Chromium layer. The depositing approaches of the Chromium layer and Copper layer can be either the electroplating or the physical vapor phase deposition (PVD).

In step 210, with reference also to FIG. 3E, two metal lines 331 which electrically connecting to the two electrodes 311, 312 of each LED chip 310 are formed by patterning the metal layer 330. The patterning of the metal layer 330 can be performed by well-known photolithography and etching process.

In step 212, with reference also to FIG. 3F, the silicon wafer 300 is cut to singularize into a plurality of silicon submounts 300a, where each silicon submount 300a comprises at least one recess 301, depending on practical requirement.

In step 214, with reference also to FIG. 3G, a phosphor layer 322 is formed on the flat top surface of the encapsulator 320. According to a preferred embodiment of the present invention, the phosphor layer 322 is formed on the flat top surface of the encapsulator 320 by utilizing a scraping knife to scrape phosphor paste on the encapsulator 320. The phosphor paste is prepared by mixing silicone and phosphor powder.

Because the phosphor layer 322 formed on the flat top surface of encapsulator 320 has a uniform thickness, it contributes the better result of wavelength conversion to the illuminating performance of LED package.

Moreover, the two metal lines 331 electrically connecting each of the LED chips 310 are extending to the bottom surface of silicon submount 300a, it makes the LED package compatible with the surface mount process.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A method for manufacturing light emitting diode (LED) package, comprising:
a) providing a silicon wafer having a top surface and a bottom surface;
b) forming a recess array on the top surface of the silicon wafer;
c) defining two through-wafer via holes in each recess;
d) flip-chip mounting a plurality of LED chips on the silicon wafer, wherein each LED chip is arranged in each of the recesses; and two electrodes of each LED chip are arranged to cover the two via holes respectively;
e) forming an encapsulator in each recess to encapsulate each LED chip, wherein each of the encapsulator has a flat top surface;
f) depositing a metal layer on the bottom surface of the silicon wafer, wherein the metal layer is electrically connected to the two electrodes of the LED chip through the two via holes;
g) forming two metal lines which electrically connecting to the electrodes of each LED chip by patterning the metal layer;
h) singularizing the silicon wafer into a plurality of silicon submounts, wherein each silicon submount comprises at least one recess; and
i) forming a phosphor layer on the top surface of each encapsulator.

2. The method in claim 1, wherein the recess array is forming by anisotropic wet etching.

3. The method in claim 1, wherein each of the recesses has a depth of 100-400 μm, and the angle between the peripheral surface of the recess and the normal direction of the bottom surface of the recess is of 45-75 degree.

4. The method in claim 1, wherein the two through-wafer via holes are forming by punching through or laser etching.

5. The method in claim 1, wherein the flat top surface of the encapsulator coincides with the top surface of the silicon wafer.

6. The method in claim 5, wherein the encapsulator is forming by multiple coatings of silicone layer.

7. The method in claim 1, wherein the metal layer has a stacked structure consisting of a chromium layer deposited on the bottom surface of the silicon wafer, and a copper layer deposited on the bottom surface of the chromium layer.

8. The method in claim 1, wherein the depositing of the metal layer is either the electroplating or the physical vapor phase deposition.

9. The method in claim 1, wherein the patterning of the metal layer is performed by photolithography and etching process.

10. The method in claim 1, wherein the forming of the phosphor layer is scraping a phosphor paste on the encapsulator.

11. A light emitting diode package, comprising:
a silicon submount having a top surface and a bottom surface, wherein at least one recess is formed on the top surface,
a LED chip flip-chip mounted in the recess, wherein two electrodes of the LED chip are arranged to cover the two via holes respectively and two through-wafer via holes defined in each recess;
an encapsulator formed in the recess to encapsulate the LED chip, wherein the encapsulator has a flat top surface;
two metal lines formed on the bottom surface of the silicon submount, wherein the two metal lines are electrically connecting to the two electrodes through the two via holes, respectively;
a phosphor layer formed on the top surface of the encapsulator.

12. The package in claim 11, wherein each of the recesses has a depth of 100-400 μm, and the angle between the peripheral surface of the recess and the normal direction of the bottom surface of the recess is of 45-75 degree.

13. The package in claim 11, wherein the flat top surface of the encapsulator coincides with the top surface of the silicon submount.

14. The package in claim 13, wherein the encapsulator is forming by multiple coatings of silicone layer.

15. The package in claim 11, wherein the metal layer has a stacked structure consisting of a Chromium layer deposited on the bottom surface of the silicon wafer, and a Copper layer deposited on the bottom surface of the Chromium layer.
